(19) United States
(12) Patent Application Publication
(10) Pub. No.: US 2015/0155854 A1
(43) Pub. Date: Jun. 4, 2015

(54) SEMICONDUCTOR CIRCUIT

(71) Applicant: RENESAS ELECTRONICS CORPORATION, Kanagawa (JP)

(72) Inventors: Keiichi HAYASAKA, Kanagawa (JP); Toyohiko YOSHIDA, Kanagawa (JP); Akira OIZUMI, Kanagawa (JP); Yoshinori TOKIOKA, Kanagawa (JP)

(73) Assignee: RENESAS ELECTRONICS CORPORATION

(21) Appl. No.: 14/547,997

(22) Filed: Nov. 19, 2014

(30) Foreign Application Priority Data
Nov. 29, 2013 (JP) 2013-247753

(51) Int. Cl. H03K 3/012; H03K 3/037

(52) U.S. Cl. CPC H03K 3/012; H03K 3/0375

(57) ABSTRACT

There is a need to provide a technology that shortens a time period from a point to start an external power supply for a microcontroller to a point to start operating a logic circuit. A stable voltage supply circuit of a semiconductor circuit accepts an external power supply VCC and supplies a VDD line with one of a power supply voltage to cause a stable output voltage and a power supply voltage to cause an unstable output voltage and fast start. At startup, the semiconductor circuit accepts an external power supply. The semiconductor circuit raises a power supply voltage to cause a stable output voltage and supplies a logic portion initialization circuit with an unstable power supply voltage to fast start, and initializes a VDD operation circuit. When the output voltage is stabilized, the semiconductor circuit changes a power supply voltage supplied to the VDD line and starts operating the VDD operation circuit.

### CROSS-REFERENCE TO RELATED APPLICATIONS

The disclosure of Japanese Patent Application No. 2013-247753 filed on Nov. 29, 2013 including the specification, drawings and abstract is incorporated herein by reference in its entirety.

### BACKGROUND

The present disclosure relates to a semiconductor device that operates under control of a microcontroller. More specifically, the disclosure relates to a technology to fast start a microcontroller.

A microcontroller is used to control various electronic devices and is applied to various products. A technology to fast start the microcontroller is examined to accelerate electronic device processing. For example, an electronic device may intermittently start to reduce the power consumption. For this purpose, the microcontroller intermittently starts according to processing needs and therefore requires the technology to fast start the microcontroller.

A technology to fast start the microcontroller is described in Japanese Unexamined Patent Application Publication No. Hei 9 (1997)-44468 (patent document 1), for example. The technology described in patent document 1 concerns a microcontroller and a control circuit including a hardware circuit whose circuit form is configured after a power-on sequence. The technology described in patent document 1 sets an operation guarantee power supply voltage for a hardware circuit to be lower than an operation guarantee power supply voltage for the microcontroller. The technology configures a hardware circuit form according to data stored in nonvolatile memory before the microcontroller starts operating after the power is turned on.

Patent Document 1: Japanese Unexamined Patent Application Publication No. Hei 9 (1997)-44468.

### SUMMARY

To ensure hardware circuit operation, the technology described in patent document 1 needs to release a microcontroller reset signal after the hardware circuit form has been configured. To ensure circuit operation, the technology described in patent document 1 assumes that a time period (second time) from a point to detect an operation guarantee power supply voltage (e.g., 4 V) in a microcontroller to a point to start operating the microcontroller is longer than a time period (first time) from a point to detect an operation guarantee power supply voltage (e.g., 3 V) in the hardware circuit to a point to complete configuration of the hardware circuit form.

However, there may be a case of ensuring operation regardless of how a power supply voltage rises. In such a case, according to the technology described in patent document 1, the time period (second time) from a point to detect an operation guarantee power supply voltage in a microcontroller to a point to start operating the microcontroller needs to be much longer than the time period (first time) from a point to detect an operation guarantee power supply voltage in the hardware circuit to a point to complete configuration of the hardware circuit form. In other words, a relatively large delay margin is needed to stably operate the microcontroller regardless of how the power supply voltage rises.

If the power supply voltage rises slowly, the technology described in patent document 1 needs to prolong the microcontroller startup for a predetermined period even though the hardware circuit form has been configured. As a result, unneeded time is consumed to start the semiconductor circuit. To solve this problem, there is a need for a technology that drastically shortens a time period from a point to start an external power supply for the microcontroller to a point to start operating the logic circuit.

These and other objects and novel features of the disclosure maybe readily ascertained by referring to the following description and appended drawings.

A semiconductor circuit according to an embodiment includes a power supply voltage supply portion and a circuit portion. The power supply voltage supply portion accepts external power supply and supplies each circuit included in the semiconductor circuit with a first power supply voltage and a second power supply voltage. The first power supply voltage ensures a stable output voltage. The second power supply voltage causes an unstable output voltage and starts faster than the first power supply voltage. The circuit portion includes a logic circuit and an initialization circuit. The logic circuit ensures operation according to the first power supply voltage. The initialization circuit ensures operation according to the second power supply voltage and initializes the logic circuit. The power supply voltage supply portion accepts the external power supply at startup of the semiconductor circuit and raises the first power supply voltage and the second power supply voltage. The power supply voltage supply portion supplies the initialization circuit of the circuit portion with the second power supply voltage to start faster than the first power supply voltage. When output of the first power supply voltage is stabilized, the power supply voltage supply portion supplies the logic circuit of the circuit portion with the first power supply voltage instead of the second power supply voltage.

The semiconductor circuit according to the embodiment controls the power supply voltage and is therefore capable of starting the logic circuit after a minimal delay elapsed from startup of an external power supply.

### BRIEF DESCRIPTION OF THE DRAWINGS

FIG. 1 illustrates operation timings of a semiconductor circuit according to a related art;

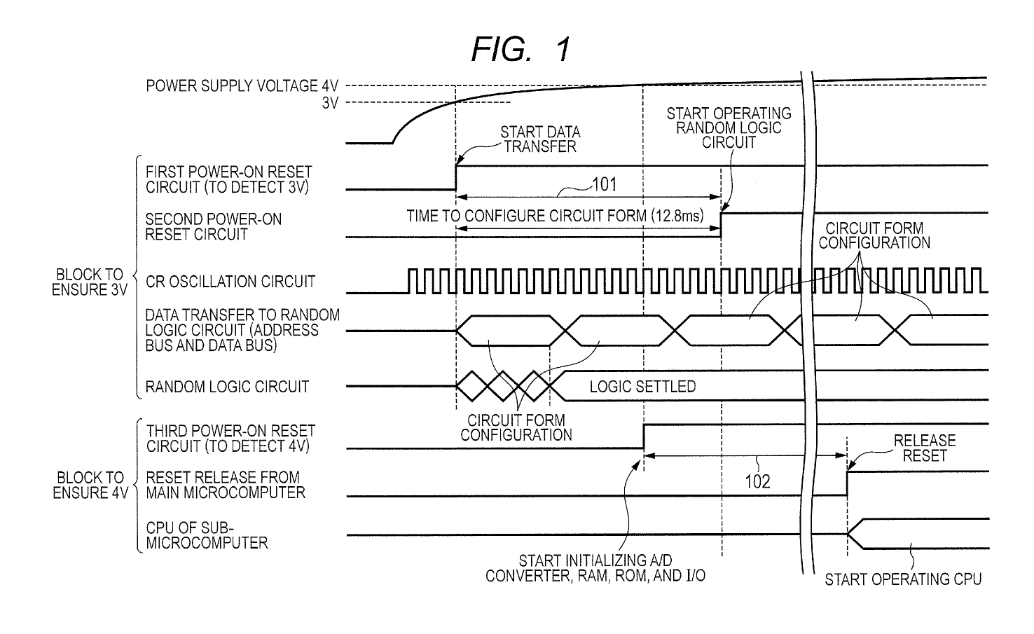

FIG. 2 is a block diagram illustrating a configuration of a semiconductor circuit 201 according to a first embodiment;

FIG. 3 illustrates operation timings of the semiconductor circuit 201 according to the first embodiment;

FIG. 4 is a block diagram illustrating a configuration of a semiconductor circuit 401 according to a second embodiment;

FIG. 5 is a block diagram illustrating a configuration of a semiconductor circuit 250 according to a third embodiment;

FIG. 6 illustrates operation timings of the semiconductor circuit 250 according to the third embodiment;

FIG. 7 is a block diagram illustrating a configuration of a semiconductor circuit 701 according to a fourth embodiment;

FIG. 8 illustrates an example of the semiconductor circuits described in the embodiments; and

FIG. 9 illustrates circuit operation.

### DETAILED DESCRIPTION

Embodiments of the semiconductor circuit according to the present disclosure will be described in further detail with reference to the accompanying drawings. Hereinafter, the same parts or components as well as the corresponding names and functions are depicted by the same reference numerals and a detailed description is omitted for simplicity.

### Related Art

A related art will be described for the purpose of comparison with the semiconductor circuit according to the embodiments. FIG. illustrates operation timings of a semiconductor circuit according to the related art. The semiconductor circuit according to the related art provides a system including a microcontroller and a hardware circuit that uses an operable voltage lower than that of the microcontroller. The hardware circuit includes a random logic circuit and initializes the microcontroller.

In this system, an external power supply operates and the power supply voltage rises to a voltage (e.g., 3 V) capable of operating the hardware circuit. A first power-on reset circuit detects a rise to the power supply voltage (3 V) and releases first reset. According to the first reset, the hardware circuit initializes the microcontroller. For this purpose, the hardware circuit transfers data to the random logic circuit to start settling a circuit form. To transfer data to the random logic circuit, the hardware circuit reads information to settle the circuit form from external ROM (read only memory) via an address bus and a data bus, for example. The semiconductor circuit allows a second power-on reset circuit to release second reset after a predetermined period (period 101) needed to settle the circuit form elapsed from the time to detect the voltage (3 V) capable of operating the hardware circuit. The second reset starts operating the random logic circuit.

The power supply voltage rises to a voltage (4 V) capable of stably operating the microcontroller. The semiconductor circuit according to the relate art then allows a third power-on reset circuit to detect a rise to the power supply voltage (4 V) and release third reset. After the third reset is released, the semiconductor circuit waits for a predetermined period (period 102) and then starts operating a CPU (central processing unit).

The period 101 is required to settle the circuit form. The period 102 ranges from detection of a voltage capable of stably operating the microcontroller to the time to start operating the CPU. The related art predetermines the period 102 to be sufficiently longer than the period 101. This can ensure CPU operation regardless of how the power supply voltage rises. According to the related art, however, a slow rise of the power supply voltage takes time to start the CPU. This is because the semiconductor circuit waits for the predetermined period 102 to start CPU operation even though the hardware circuit completes the initialization.

To solve this problem, the semiconductor circuit according to the first embodiment accepts an external power supply and concurrently starts a stable voltage supply circuit to output an internal power supply voltage and starts (initializes) the logic circuit. The semiconductor circuit thereby accelerates the startup process.

### First Embodiment

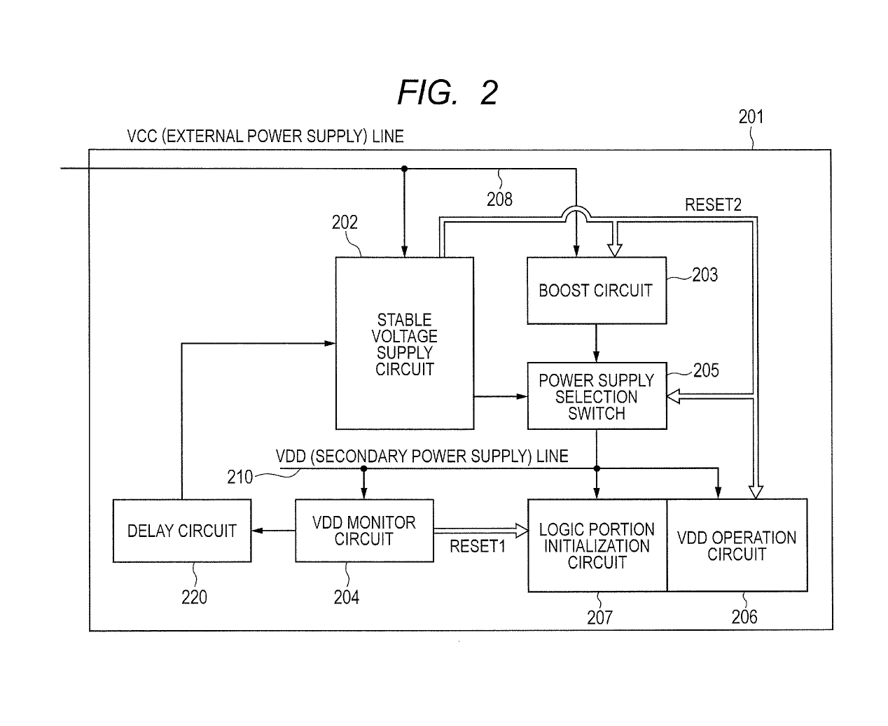

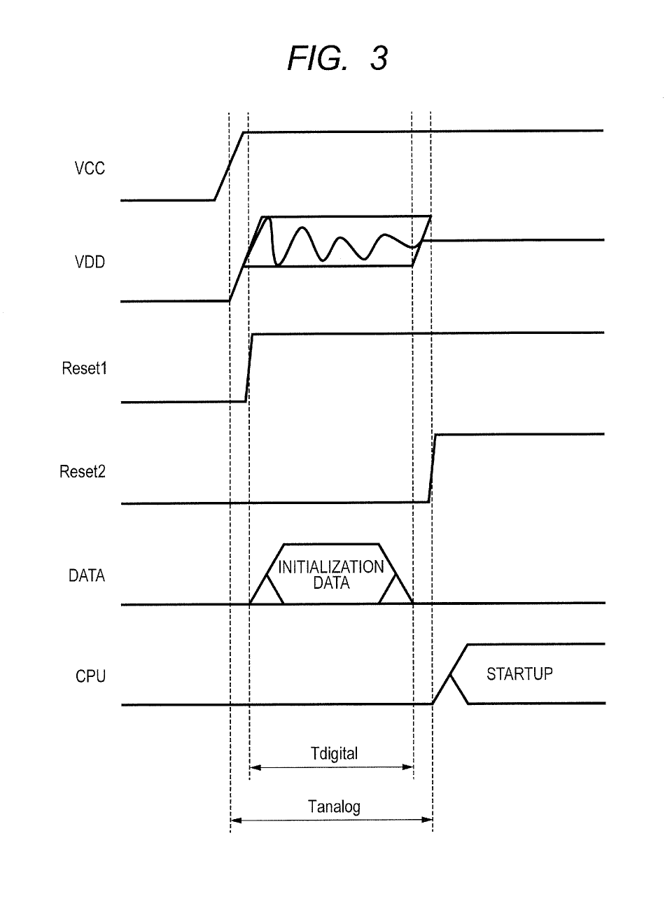

With reference to FIGS. 2 and 3, the following describes the semiconductor circuit according to the first embodiment. FIG. 2 is a block diagram illustrating a configuration of a semiconductor circuit 201 according to the first embodiment.

As illustrated in FIG. 2, the semiconductor circuit 201 includes a stable voltage supply circuit 202, a boost circuit 203, a VDD monitor circuit 204, a power supply selection switch 205, a VDD operation circuit 206, a logic portion initialization circuit 207, and a delay circuit 220. The semiconductor circuit 201 accepts the external power supply from a VCC (external power supply) line 208 and supplies the power to the stable voltage supply circuit 202 and the boost circuit 203. Though not illustrated, a power supply voltage output from the stable voltage supply circuit 202 is supplied to the VDD monitor circuit 204, the VDD operation circuit 206, the logic portion initialization circuit 207, and the other circuits in the semiconductor circuit 201 via the VDD line 210.

The stable voltage supply circuit 202 accepts the external power supply via the VCC line 208 and supplies a stable VDD voltage to a circuit inside the semiconductor circuit 201. The stable voltage supply circuit 203 accepts signal Reset1 from the delay circuit 220. When VDD voltage output is stabilized, the stable voltage supply circuit 203 releases signal Reset2.

The boost circuit 203 accepts the external power supply via the VCC line 208, fast raises the voltage, and outputs it to the power supply selection switch 205. The boost circuit 203 fast starts but generates an instable output voltage compared to the stable VDD voltage output from the stable voltage supply circuit 202.

The VDD monitor circuit 204 monitors a VDD voltage supplied to the VDD line 210. When the VDD voltage rises to enable the logic portion initialization circuit 207 to operate, the VDD monitor circuit 204 outputs signal Reset1 to the logic portion initialization circuit 207 and the delay circuit 220.

The power supply selection switch 205 selects a power supply source supplied to the VDD line 210. The power supply selection switch 205 accepts a voltage (first power supply voltage) output from the stable voltage supply circuit 202 and a voltage (second power supply voltage) output from the boost circuit 203. The power supply selection switch 205 supplies the VDD line 210 with one of voltages output from the stable voltage supply circuit 202 and the boost circuit 203. The power supply selection switch 205 supplies the VDD line 210 with the voltage output from the boost circuit 203 until the stable voltage supply circuit 202 releases signal Reset2. When the stable voltage supply circuit 202 releases signal Reset2, the power supply selection switch 205 supplies the VDD line 210 with the voltage output from the stable voltage supply circuit 202.

The VDD operation circuit 206 corresponds to a logic circuit that includes a CPU and operates on a VDD voltage supplied from the stable voltage supply circuit 202. Only a stable VDD voltage ensures operation of the VDD operation circuit 206. The VDD operation circuit 206 starts operating when receiving signal Reset2 from the stable voltage supply circuit 202.

The logic portion initialization circuit 207 initializes the VDD operation circuit 206. Even an unstable VDD voltage ensures operation of the logic portion initialization circuit 207 if the VDD voltage is higher than or equal to a specified value. For example, the VDD operation circuit 206 initializes flash trimming data (write or erase pulse width), USB (Universal Serial Bus) trimming data, the number of retries, ECC (Error Check and Correct memory), read current, reference current, control circuit operating voltage, internal clock frequency, clock gating for SRAM (Static Random Access Memory), flash memory clock gating, and a reset option to start the power supply. The semiconductor circuit may initialize an analog circuit. For example, the semiconductor circuit initializes trimming data (temperature and voltage) for BGR (Band Gap Reference), trimming data (reference current and read voltage trimming) for flash memory, and trimming data for built-in oscillators such as HOCO (High-speed on chip oscillator) and LOCO (Low-speed on chip oscillator).

Signal Reset1 indicates that the VDD voltage rises to enable the logic portion initialization circuit 207 to operate. The delay circuit 220 accepts signal Reset1 from the VDD monitor circuit 204, causes a delay during a predetermined period, and then outputs signal Reset1 to the stable voltage supply circuit 202. The delay circuit 220 causes the delay needed for the logic portion initialization circuit 207 to initialize the VDD operation circuit 206 and then outputs signal Reset1 to the stable voltage supply circuit 202.

FIG. 3 illustrates operation timings of the semiconductor circuit 201 according to the first embodiment. As seen from voltage “VCC” in FIG. 3, the semiconductor circuit 201 accepts the external power supply VCC and then allows the boost circuit 203 to fast raise the VDD voltage. As seen from voltage “VDD” in FIG. 3, the boost circuit 203 outputs an unstable voltage.

As seen from signal “Reset1,” the VDD monitor circuit 204 monitors the VDD voltage supplied to the VDD line 210. The VDD monitor circuit 204 releases signal Reset1 when the VDD voltage rises to enable the logic portion initialization circuit 207 to operate. According to the example in FIG. 3, the VDD monitor circuit 204 raises signal Reset1 to release signal Reset1.

As seen from signal “Reset2,” signal Reset2 is not released until the stable voltage supply circuit 202 outputs a stable VDD voltage.

As seen from data “DATA,” signal Reset1 is output from the VDD monitor circuit 204 to the logic portion initialization circuit 207 that thereby starts operating. The logic portion initialization circuit 207 can operate on an unstable voltage output from the boost circuit 203. The logic portion initialization circuit 207 starts reading data from ROM outside the semiconductor circuit 201 and performs initialization needed to operate the VDD operation circuit 206. The initialization needed requires time Tdigital.

As seen from voltage “VDD,” time Tanalog elapses until the stable voltage supply circuit 202 accepts the external power supply VCC and outputs a stable VDD voltage. As seen from signal “Reset2,” the stable voltage supply circuit 202 outputs signal Reset2 when the VDD voltage output becomes stable. As seen from circuit “CPU,” the VDD operation circuit 206 is supplied with output of signal Reset2 and a stable VDD voltage from the stable voltage supply circuit 202 to start operating.

### Overview of First Embodiment

In the semiconductor circuit 201 according to the first embodiment, the delay circuit 220 ensures the delay time that starts from a rise of signal Reset1 and is needed to initialize the VDD operation circuit 206. After the delay time is ensured, the stable voltage supply circuit 202 raises signal Reset2. The stable voltage supply circuit 202 is capable of operation because the VDD voltage is under control of the power supply system. When the stable voltage supply circuit 202 releases signal Reset2, the VDD line 210 is uncoupled from the boost circuit 203 and is coupled to the stable voltage supply circuit 202. The stable voltage supply circuit 202 then supplies the stable VDD voltage. To make a comparison between the related art and the semiconductor circuit 201 according to the first embodiment, the related art does not control the power supply voltage and requires a large delay margin after the power supply voltage is stabilized in order to ensure the stable startup regardless of any rising voltage waveforms. By contrast, the semiconductor circuit 201 according to the first embodiment initializes the logic circuit under control of the VDD voltage and is capable of starting the logic circuit using a minimum delay from a rise of the external power supply.

Another related art initializes the logic circuit after the VDD voltage is stabilized. By contrast, the semiconductor circuit 201 according to the first embodiment initializes the logic circuit and starts the power supply circuit in parallel. The semiconductor circuit 201 can shorten the time required until the logic circuit starts.

### Second Embodiment

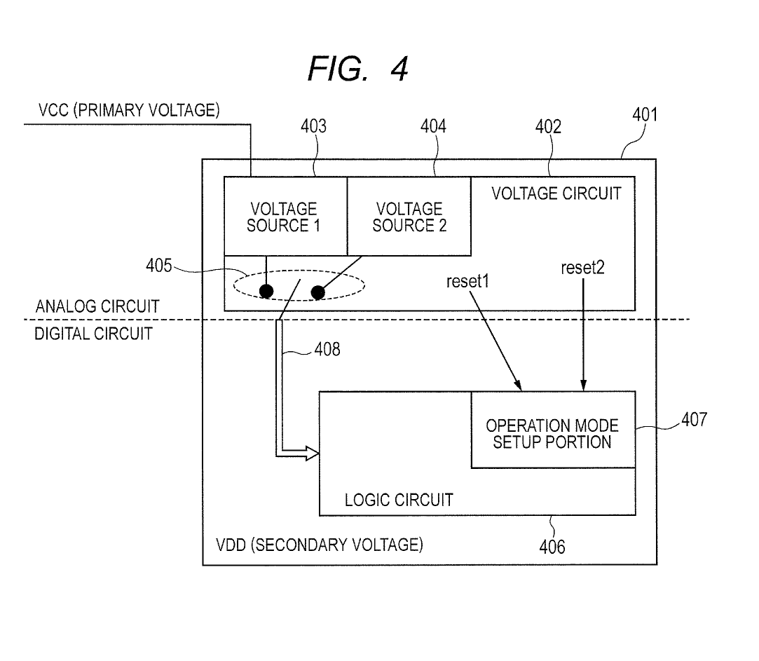

With reference to FIG. 4, the following describes a semiconductor circuit 401 according to the second embodiment. FIG. 4 is a block diagram illustrating a configuration of the semiconductor circuit 401 according to the second embodiment.

As illustrated in FIG. 4, the semiconductor circuit 401 includes a voltage circuit 402 and a logic circuit 406.

The semiconductor circuit 401 is supplied with external power from VCC (external power supply) and supplies a VDD voltage to the logic circuit 406 via a VDD line 408. As illustrated in FIG. 4, the semiconductor circuit 401 includes at least two voltage sources such as a first voltage source 403 and a second voltage source 404. The first voltage source 403 fast starts to raise a voltage but outputs an unstable voltage. The second voltage source 404 operates slower than the first voltage source 403 but outputs a stable VDD voltage. The semiconductor circuit 401 includes a changeover switch 405 to supply the VDD line 408 with an output voltage from the first voltage source 403 or the second voltage source 404.

The logic circuit 406 includes an operation mode setup portion 407. The operation mode setup portion 407 stores operation mode of the logic circuit 406. Available operation modes include a low-speed-only mode and a normal mode. The low-speed-only mode allows the logic circuit 406 to operate on an unstable VDD voltage supplied from the first voltage source 403 and limits functions executable in the logic circuit 406. The normal mode allows the logic circuit 406 to operate on a stable VDD voltage supplied from the second voltage source 404 and permits operations compliant with full specifications.

Immediately after the external power supply is turned on, the semiconductor circuit 401 starts the first voltage source 403 and the second voltage source 404. The semiconductor circuit 401 allows the changeover switch 405 to select the first voltage source 403 and supply an unstable voltage to the VDD line 408. The semiconductor circuit 401 outputs signal Reset1 to the operation mode setup portion 407 when the voltage output from the first voltage source 403 rises to a voltage needed for operation in the low-speed-only mode.

The logic circuit 406 operates in the low-speed-only mode to operate on the unstable VDD voltage. The logic circuit 406 accepts signal Reset1 from the semiconductor circuit 401 to perform the initialization in the low-speed-only mode needed for operation of the logic circuit 406.

After the second voltage source 404 starts, a voltage output from the second voltage source 404 is stabilized. The semiconductor circuit 401 then allows the changeover switch 405 to select the second voltage source 404 and output a stable VDD voltage from the second voltage source 404 to the VDD line 408. The semiconductor circuit 401 outputs signal Reset2 to the operation mode setup portion 407 when a voltage output from second voltage source 404 reaches the stable VDD voltage. The semiconductor circuit 401 outputs signal Reset1 and, followed by a lapse of the predetermined period needed to initialize the logic circuit 406 operating in the low-speed-only mode, the voltage output from the second voltage source 404 is stabilized. In this case, the semiconductor circuit 401 may output signal Reset2 to the operation mode setup portion 407.

The operation mode setup portion 407 accepts signal Reset2 from the semiconductor circuit 401 to change the operation mode of the logic circuit 406 to the normal mode. The logic circuit 406 starts operating in the normal mode because signal Reset2 indicates that the VDD voltage is stable.

### Overview of Second Embodiment

The semiconductor circuit 401 according to the second embodiment starts the external power supply, stabilizes a VDD voltage output, and initializes the logic circuit during operation under an unstable voltage while controlling the VDD voltage. The semiconductor circuit 401 accordingly shortens the time required to start operating the logic circuit after starting the external power supply. The semiconductor circuit 401 according to the second embodiment provides the voltage circuit with several voltage sources with different characteristics. The semiconductor circuit 401 can thereby stabilize the VDD voltage and initialize the logic circuit in parallel after the external power supply is turned on.

### Third Embodiment

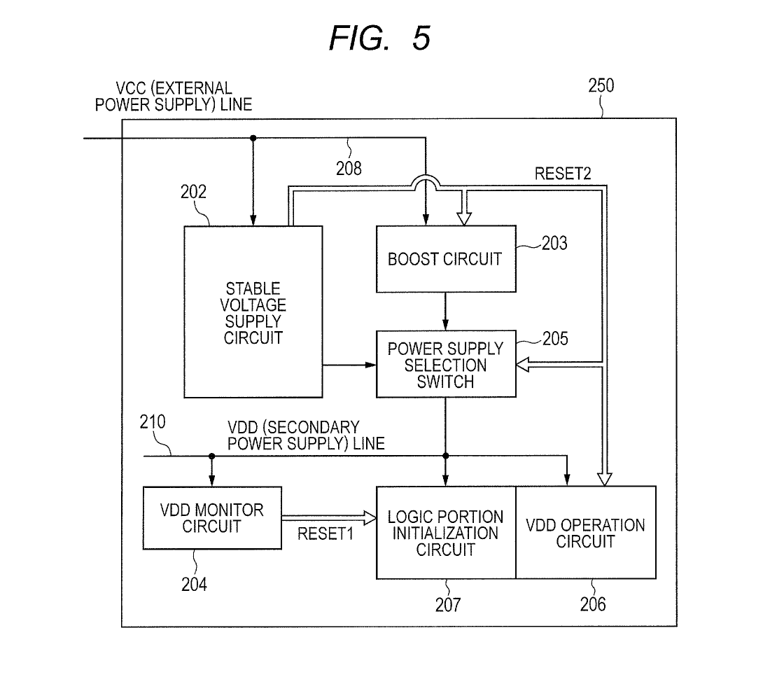

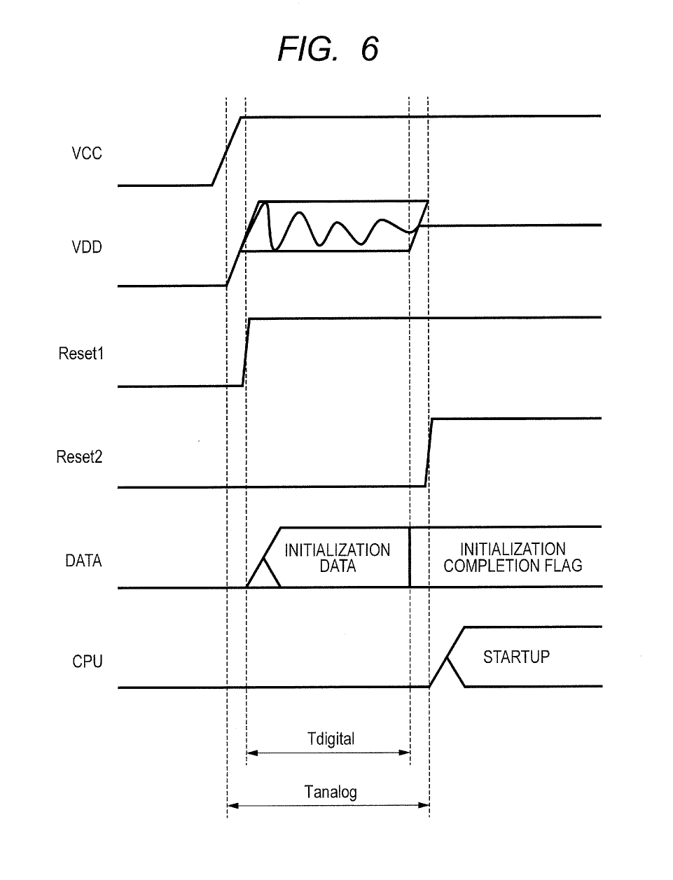

With reference to FIGS. 5 and 6, the following describes the semiconductor circuit according to the third embodiment. FIG. 5 is a block diagram illustrating a configuration of a semiconductor circuit 250 according to the third embodiment.

To make a comparison between the semiconductor circuit 250 illustrated in FIG. 5 and the semiconductor circuit 201 according to the first embodiment, the semiconductor circuit 250 according to the third embodiment differs from the semiconductor circuit 201 according to the first embodiment in that the semiconductor circuit 250 does not include the delay circuit 220.

In the semiconductor circuit 250 according to the third embodiment, the logic portion initialization circuit 207 initializes the VDD operation circuit 206. When the VDD operation circuit 206 has been initialized, the logic portion initialization circuit 207 sets an initialization completion flag indicating completion of the initialization.

The VDD operation circuit 206 accepts signal Reset2 from the stable voltage supply circuit 202 and starts the CPU if both signal Reset2 and the initialization completion flag are “true.”

FIG. 6 illustrates operation timings of the semiconductor circuit 250 according to the third embodiment. As seen from data “DATA,” the logic portion initialization circuit 207 initializes the VDD operation circuit 206. When the initialization is completed, the logic portion initialization circuit 207 sets the initialization completion flag.

As seen from circuit “CPU,” the VDD operation circuit 206 starts operating using the stable VDD voltage supplied from the stable voltage supply circuit 202 when the output of signal Reset2 and the initialization completion flag are both “true.”

### Overview of Third Embodiment

Unlike the semiconductor circuit 201 according to the first embodiment, the semiconductor circuit 250 according to the third embodiment need not provided the delay circuit 220 and logically ensures completion of the initialization when the CPU of the VDD operation circuit 206 starts. For example, the delay circuit 220 may be subject to large performance variations at the time of manufacture. In such a case, the semiconductor circuit 250 can logically ensure completion of the initialization instead of the delay circuit 220 to improve the semiconductor circuit quality.

### Fourth Embodiment

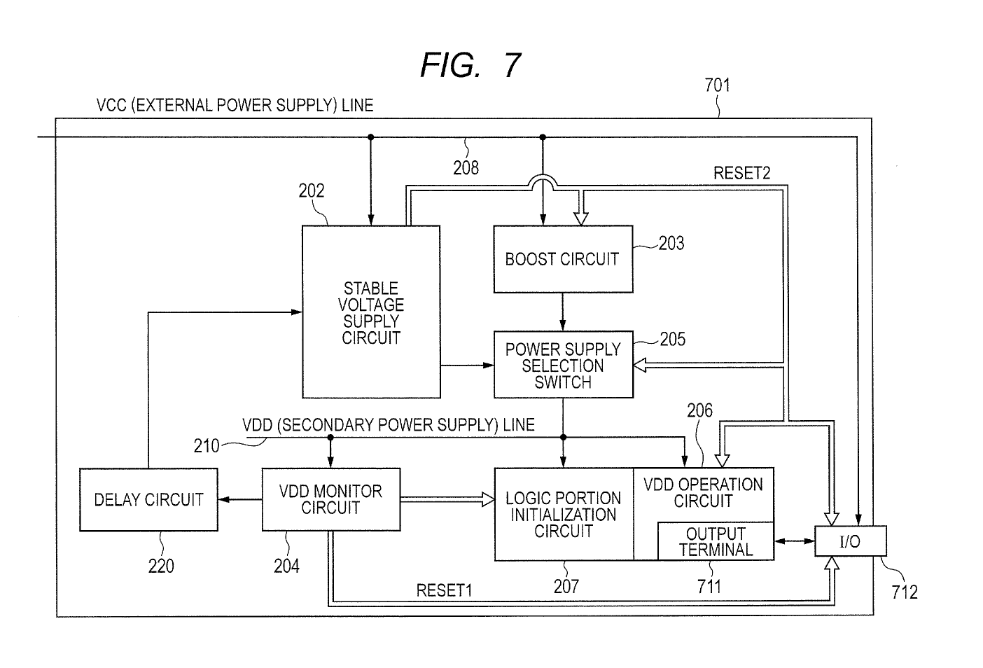

With reference to FIG. 7, the following describes the semiconductor circuit according to the fourth embodiment. FIG. 7 is a block diagram illustrating a configuration of a semiconductor circuit 701 according to the fourth embodiment.

To make a comparison between the semiconductor circuit 701 illustrated in FIG. 7 and the semiconductor circuit 201 according to the first embodiment, the semiconductor circuit 701 differs from the semiconductor circuit 201 according to the first embodiment in that the semiconductor circuit 701 includes an input/output terminal (I/O 712) operating on the external power supply (VCC) and the VDD operation circuit 206 includes an output terminal 711.

The VDD monitor circuit 204 monitors a VDD voltage supplied to the VDD line 210 and outputs signal Reset1 to the I/O 712 when the VDD voltage rises to a voltage that enables the logic portion initialization circuit 207 to operate.

The I/O 712 accepts signal Reset1 from the VDD monitor circuit 204 to uncouple the I/O 712 from the output terminal 711 of the VDD operation circuit 206. The I/O 712 accepts signal Reset1 from the stable voltage supply circuit 202 to couple the I/O 712 with the output terminal 711.

### Overview of Fourth Embodiment

In the semiconductor circuit 701 according to the fourth embodiment, the VDD operation circuit 206 is uncoupled from the I/O 712 during a period that does not ensure operation of the VDD operation circuit 206. The semiconductor circuit 701 is uncoupled from the communication with the outside. While operation of the VDD operation circuit 206 is not ensured, the semiconductor circuit 701 does not generate unstable output to the outside and is capable of decreasing a possibility of malfunction.

### Example of Circuit

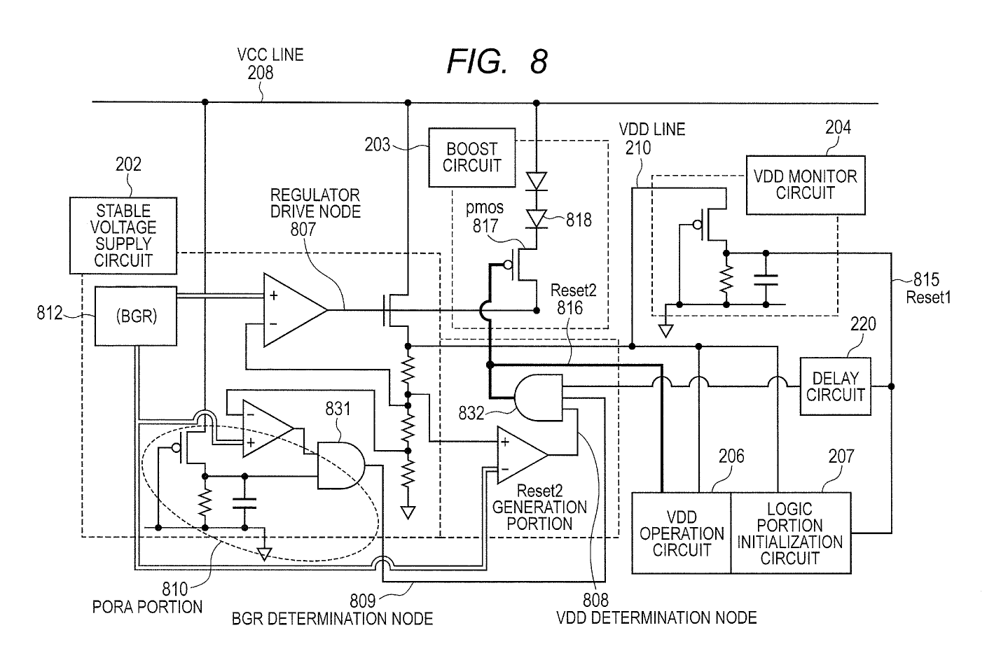

FIG. 8 illustrates an example of the semiconductor circuits described in the embodiments. The semiconductor circuit illustrated in FIG. 8 corresponds to the semiconductor circuit 201 according to the first embodiment.

As illustrated in FIG. 8, an external power supply voltage is supplied from the VCC line 208 to the stable voltage supply circuit 202 and the boost circuit 203. A regulator drive node 807 is included in the stable voltage supply circuit 202 and determines an output voltage output to the VDD line 210. A BGR (Band-gap reference) circuit 812 outputs a reference voltage.

The VDD determination node 808 compares a divided voltage from the semiconductor circuit 201 with the reference voltage output from the BGR circuit 812 to determine whether the VDD voltage supplied to the VDD line 210 is stable. The VDD determination node 808 may generate unstable output when the semiconductor circuit 201 is turned on. When the VDD voltage is stable, the VDD determination node 808 outputs value “H.”

A BGR determination node 809 compares a divided voltage from the VDD line 210 with an output from the BGR circuit 812 to determine whether the BGR circuit 812 rises. As illustrated in FIG. 8, the BGR determination node 809 supplies an AND circuit 831 with a result of comparison between the divided voltage from the VDD line 210 and the output from the BGR circuit 812 and supplies the AND circuit 831 with an output from a PORA (Power On Reset) portion 810. The BGR determination node 809 thereby eliminates a possibility of allowing the semiconductor circuit 201 to malfunction due to a low voltage. The BGR determination node 809 outputs value “H” while the output from the BGR circuit 812 is stable.

Inputs to an AND circuit 832 include an output from the VDD determination node 808, an output from the BGR determination node 809, and signal Reset1 that is delayed by the delay circuit 220 long enough to initialize the logic circuit. If all the input values are set to “H,” signal Reset2 is released to separate the output of the boost circuit 203 from the VDD line 210.

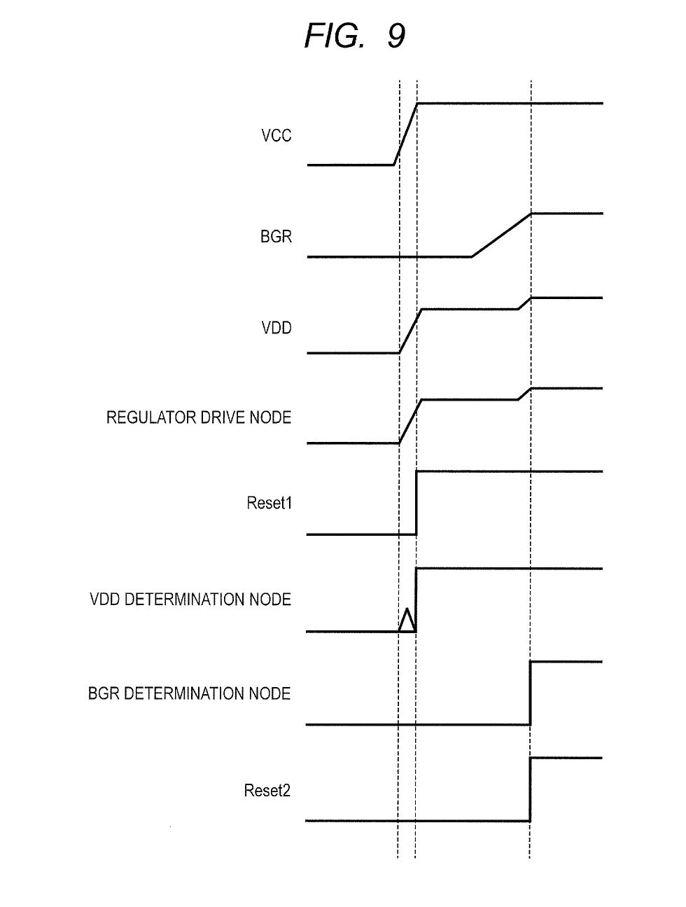

FIG. 9 illustrates circuit operation. As seen from signal “VCC,” the VCC line 208 rises when external power supply voltage VCC is input to the semiconductor circuit 201. When the external power supply voltage VCC rises, the PORA portion 810 ensures value “L” for output from the BGR determination node 809 as seen from value “BGR determination node.” Therefore, as seen from signal “Reset2,” a Reset2 signal line 816 is set to value “L.”

When a voltage of the VCC line 208 rises, the regulator drive node 807 is coupled to the VCC line 208 via a PMOS (positive channel Metal Oxide Semiconductor) 817 to increase the voltage. As seen from voltage “VDD,” increasing the voltage of the regulator drive node 807 also increases the voltage supplied to the VDD line 210 by the boost circuit 203. The boost circuit 203 is provided with a diode 818 including diodes in several stages and protects a circuit inside the semiconductor circuit 201 against an excessive voltage supplied from the VCC line 208.

As seen from signal “Reset1, ” signal Reset1 is released when the voltage supplied to the VDD line 210 by the boost circuit 203 increases to a voltage capable of operating the logic portion initialization circuit 207. The logic portion initialization circuit 207 starts operating and reads data from external nonvolatile memory to perform initialization needed to operate the VDD operation circuit 206.

Inputs to an AND circuit 832 include the BGR determination node 809, the VDD determination node 808, and signal Reset1. If all the input values are set to “H,” signal Reset2 is released as seen from signal “Reset2.”

Releasing signal Reset2 uncouples the boost circuit 203 from the regulator drive node 807. The stable voltage supply circuit 202 drives the regulator drive node 807 to supply a stable VDD voltage to the VDD line 210. The VDD operation circuit 206 accepts signal Reset2 and starts operating using the stable VDD voltage.

The semiconductor circuit described in the above-mentioned embodiments is used for a semiconductor device and its system required to fast start. For example, the semiconductor circuit described in the above-mentioned embodiments is used for semiconductor devices or system LSI chips incorporated in a microcomputer that contains a power supply circuit. While the above-mentioned embodiments have been described, it is obviously favorable to combine the embodiments.

While there has been described the specific preferred embodiment of the present invention created by the inventors, it is to be distinctly understood that the present invention is not limited thereto but may be otherwise variously embodied within the spirit and scope of the invention.

All the disclosed embodiments just provide examples and must be considered to be nonrestrictive. The scope of the invention is defined by the appended claims, not the above description, and is intended to include meanings equivalent to the claims and all modifications within the claims.

What is claimed is:

1. A semiconductor circuit comprising:
a power supply voltage supply portion that accepts external power supply and supplies each circuit included in the semiconductor circuit with a first power supply voltage and a second power supply voltage, in which the first power supply voltage ensures a stable output voltage and the second power supply voltage causes an unstable output voltage and starts faster than the first power supply voltage; and
a circuit portion including a logic circuit and an initialization circuit, in which the logic circuit ensures operation according to the first power supply voltage and the initialization circuit ensures operation according to the second power supply voltage and initializes the logic circuit,
wherein the power supply voltage supply portion accepts the external power supply at startup of the semiconductor circuit, raises the first power supply voltage and the second power supply voltage, supplies the initialization circuit of the circuit portion with the second power supply voltage to start faster than the first power supply voltage, and, when output of the first power supply voltage is stabilized, supplies the logic circuit of the circuit portion with the first power supply voltage instead of the second power supply voltage.

2. The semiconductor circuit according to claim 1, further comprising:
a VDD monitor circuit to monitor a VDD voltage for the circuit portion,
wherein the VDD monitor circuit detects an increase in the VDD voltage of the circuit portion to reach a voltage capable of allowing the initialization circuit to perform the initialization and outputs, to the initialization circuit, a signal indicating operability of the initialization circuit according to the detection,
wherein the initialization circuit receives a signal indicating operability of the initialization circuit from the VDD monitor circuit and starts the initialization, and
wherein the power supply voltage supply portion supplies the first power supply voltage to the logic circuit when it is detected that output of the first power supply voltage is stable and the initialization circuit performs the initialization based on a signal output from the VDD monitor circuit.

3. The semiconductor circuit according to claim 2,
wherein the semiconductor circuit includes a delay circuit, and
wherein the delay circuit receives a signal indicating operability of the initialization circuit and outputs a signal indicating initialization performed by the initialization circuit to the power supply voltage supply portion after a predetermined period required for the initialization.

4. The semiconductor circuit according to claim 1,
wherein the power supply voltage supply portion includes a boost circuit and a selection portion, the boost circuit being configured to receive the first power supply voltage and output the second power supply voltage and the selection portion being configured to select one of the first power supply voltage and the second power supply voltage to be supplied to the circuit portion, and
wherein the selection portion couples output of the boost circuit to a VDD line at startup of the semiconductor circuit, when output of the first power supply voltage is stabilized, uncouples the boost circuit from the VDD line, and supplies the first power supply voltage to the VDD line.

5. The semiconductor circuit according to claim 1,
wherein the circuit portion is capable of specifying an operation mode and operates in at least one of a limited mode and a normal mode as an operation mode, the limited mode being configured to limit an executable function and enable operation using the second power supply voltage as an unstable voltage and the normal mode being configured to enable operation using the first power supply voltage,
wherein the power supply voltage supply portion supplies the circuit portion with the second power supply voltage at startup of the semiconductor circuit,
wherein the circuit portion is supplied with the second power supply voltage, operates in the limited mode, and allows the initialization circuit to perform the initialization,
wherein, when output of the first power supply voltage is stabilized, the power supply voltage supply portion outputs a signal allowing the circuit portion to operate in the normal mode to the circuit portion, and supplies the circuit portion with the first power supply voltage, and
wherein the circuit portion receives a signal to enable operation in the normal mode, changes the operation mode to the normal mode, and is supplied with the first power supply voltage, and allows the logic circuit to operate.

6. The semiconductor circuit according to claim 1,
wherein, at the initialization, the initialization circuit enables initialization completion data indicating completion of the initialization, and
wherein the logic circuit starts operating when receiving a signal from the power supply voltage supply portion indicating stabilized output voltage of the first power supply voltage and reading the enabled initialization completion data.

7. The semiconductor circuit according to claim 1,
wherein the semiconductor circuit includes a first input/output portion operating using the external power supply,
wherein the logic circuit includes a second input/output portion, and
wherein, when the second power supply voltage increases to a voltage capable of the initialization, the first input/output portion is uncoupled from the second input/output portion of the logic circuit and, when output voltage of the first power supply voltage is stabilized and the first power supply voltage is supplied to the logic circuit, the first input/output portion is coupled to the second input/output portion.
